(19) United States
(12) Patent Application Publication
(10) Pub. No.: US 2025/0113645 A1
(43) Pub. Date: Apr. 3, 2025

(54) AN APPARATUS FOR MANUFACTURING AN ELECTRODE ASSEMBLY

(71) Applicant: REC Solar PTE. Ltd., Singapore (SG)

(72) Inventors: Thiyagu SUBRAMANI, Singapore (SG); Chin Keong SEE, Singapore (SG); Bjorn ANDERSSON, Singapore (SG); Thein Aung Victor LYNN, Singapore (SG)

(73) Assignee: REC Solar PTE. Ltd., Singapore (SG)

(21) Appl. No.: 18/725,078

(22) PCT Filed: Dec. 9, 2022
(86) PCT No.: PCT/EP2022/085153

§ 371 Date: Jun. 27, 2024

(30) Foreign Application Priority Data
Dec. 29, 2021 (GB) 2119063.2

(51) Int. Cl. H10F 71/00; H10F 77/20

(52) U.S. Cl. CPC H10F 71/1375; H10F 77/219

(57) ABSTRACT

An apparatus for manufacturing an electrode assembly for connecting a front surface of a first solar cell to a back surface of a second solar cell, the electrode assembly comprising a plurality of conductive elements arranged substantially parallel to one another in a longitudinal direction and substantially spaced apart in a transverse direction, the apparatus comprising: a first roll and a second roll spaced apart to define a gap therebetween for receiving the plurality of conductive elements; and an actuator configured to rotate at least one of the first and second rolls; wherein the apparatus is configured to periodically reduce the gap between the first and second rolls to periodically apply a compressive force to the plurality of conductive elements arranged in the gap when the at least one of the first and second rolls rotates.

### CROSS-REFERENCE TO RELATED APPLICATIONS

This application is a U.S. National Phase Patent Application based on International Patent Application No. PCT/EP2022/085153, filed Dec. 9, 2022; which claims priority to GB Patent Application No. 2119063.2, filed Dec. 29, 2021. The above referenced applications are incorporated herein by reference in their entirety as if fully set forth herein.

### FIELD OF THE DISCLOSURE

The present disclosure relates to an apparatus for manufacturing an electrode assembly for a solar cell assembly, and to a method of the same. The disclosure further relates to a method of manufacturing a solar cell assembly, an electrode assembly and to a solar cell assembly.

### BACKGROUND

Solar modules for providing electrical energy from sunlight comprise an array of cells, each comprising a photovoltaic element, or substrate. The solar cells are typically connected so that electrical current is routed, via an electrical connector, from one solar cell to another. Each of the electrical connectors comprises a plurality of electrically conductive elements (e.g. wires) which form an electrical connection with electrodes (e.g. finger electrodes) arranged on the respective front and back surfaces of the solar cells.

A general aim for solar cell development is to attain high conversion efficiency balanced by a need for reduced production costs. Efforts to achieve this have focused on the electrical connections between the solar cells. Despite these efforts, there remains a need to improve the electrical connections between the solar cells.

### SUMMARY

According to a first aspect of the invention there is provided an apparatus for manufacturing an electrode assembly for connecting a front surface of a first solar cell to a back surface of a second solar cell. The electrode assembly may comprise a plurality of conductive elements arranged substantially parallel to one another in a longitudinal direction and substantially spaced apart in a transverse direction. The apparatus comprises: a first roll (e.g. roller) and a second roll (e.g. roller) which are spaced apart to define a gap therebetween for receiving the plurality of conductive elements; and an actuator configured to rotate at least one of the first and second rolls; wherein the apparatus is configured to periodically reduce the gap between the first and second rolls to periodically apply a compressive force to the plurality of conductive elements arranged in the gap when the at least one of the first and second rolls rotates.

In general, the apparatus provides a convenient means of forming periodically compressed sections in the plurality of conductive elements of an electrode assembly. The resulting compressed sections are advantageously configured to be arranged within an overlapping region of the first and second solar cells to provide a more stable mechanical connection therebetween.

According to a particular type of solar module, the solar cells can be arranged in a ‘gapless’ configuration in which the front surface of the first solar cell is partially overlapped by the back surface of the second solar cell. In this situation, the conductive elements (e.g. electrical connectors, or wires) extend from the first solar cell to the second solar cell across the overlapping region and are typically soldered to the respective surfaces of the solar cells.

When the solar cells are in use, stresses caused by mechanical loading and temperature changes can build up at the overlapping region. In the case of round conductive elements (e.g. wires comprising a circular cross-section), these stresses tend to concentrate at the interfaces between the solar cells and the conductive elements, which can lead to cracks forming in the solder.

One approach to solving this problem has been to provide conductive elements that are configured with a rectangular profile (e.g. conductive ribbons), which increase the contact area between the ribbon and the solar cell surface at the overlap region. The larger contact area leads to a reduction in the concentration of stresses in the overlapping region. However, such ribbons are less effective at scattering incoming light, at least compared to round wires, which can thereby lead to a reduction in the absorption conditions at the front surface of the solar cell.

As described above, the apparatus according to the first aspect of the present invention is configured to fabricate a plurality of conductive elements comprising a compressed section which can be arranged within the overlapping region of the solar cells. The compressed section provides a more stable mechanical coupling between the solar cells in the overlapping region. The improved mechanical stability of the overlapping region thereby increases the strength and reliability of the solar cell assembly, which extends the operational life of the solar module and reduces the associated maintenance costs. Further, the non-compressed sections of the conductive elements can be arranged on the front and back surfaces of the first and second solar cells in order to increase light scattering, and thereby increase the operating efficiency of the solar cells.

Further, the rotation of the first and second rolls enables the compression of the conductive elements' periodic sections to proceed, continuously. In this way, the rolls are configured to reduce the height of the section without having to stop (e.g. pause or halt) the fabrication of the electrode, which thereby improves the efficiency of the manufacturing process.

Optional features will now be set out. These are applicable singly or in any combination with any aspect.

The first roll and the second roll may be substantially axially parallel and radially spaced apart from each other, to define the gap therebetween. Accordingly, the rotation axis of the first roll may be aligned in parallel with the rotation axis of the second roll.

The apparatus may be configured to periodically not apply the compressive force to the plurality of conductive elements. The apparatus may be configured to alternate between applying the compressive force and not applying the compressive force. Accordingly, the apparatus may be configured to periodically not apply a compressive force (i.e. a force capable of causing a substantial reduction to the thickness of the conductive elements) along the entire length of the conductive elements. The successive periodic sections having reduced thicknesses may define compressed (e.g. deformed or flattened) sections of the conductive elements which are interleaved with (e.g. alternate with) non-compressed sections of the conductive elements (e.g. in a sequence: compressed, non-compressed, compressed, non-compressed, etc.).

In embodiments, the resulting conductive elements may be configured with a compressed section arranged between two non-compressed sections. The compressed section can be arranged in the overlapping region between two solar cells and the non-compressed sections can be arranged on the respective front and back surfaces of the partially overlapping solar cells.

The front surface of the solar cell may define the surface of the solar cell upon which light is incident when the solar cell assembly is in use (e.g. the frontmost surface of the solar cell). The back surface of the solar cell will define the surface of the solar cell which is opposite the front surface (e.g. the backmost surface of the solar cell). The back surface of the solar cell may not be directly exposed to incident light during use. The solar cell assembly may be configured so that light transmitted (e.g. not absorbed) from front to back through the solar cell is then reflected back towards the solar cell's back surface, which provides a further opportunity for the light to absorbed.

The reduction in the height of the compressed section causes ‘spread’ of the material forming the conductive element. The material may be spread in a transverse direction (e.g. a direction perpendicular to the movement of the element through the gap). This deformation causes an increase in the width of the compressed section compared to the non-compressed sections (e.g. which may be arranged either side of (i.e. before and after) the compressed sections). The deformation of the conductive element between the rolls also creates a force that pushes the rolls apart (i.e. in opposition to the compressive force exerted by the rolls upon the conductive elements). This separating force, or rolling load, may increase as the conductive element is compressed between the rolls, as would be understood by the skilled person.

The first roll may be configured to rotate in an opposite direction to the second roll, and vice versa. This ensures that the rolls don't act against each other whilst pulling the conductive elements through the gap.

The first and second rolls may be configured to each rotate at substantially the same speed (e.g. the rolls rotate at substantially the same revolutions per minute), which prevents rubbing between the roll and the conductive elements.

The second roll may be arranged substantially above the first roll. The gap between the rolls may, therefore, be defined by two substantially vertical openings arranged either side of the gap. The conductive elements can be fed through one of the vertical openings (e.g. a first opening) in a horizontal direction. During the operation of the apparatus, the conductive elements may be pulled through the gap (e.g. by rotation of at least one of the rolls), and then pushed out of the other of the vertical openings (e.g. a second opening).

A contact angle may be defined as the enclosed angle between a first line from a point where the conductive element first contacts one of the rolls to the centre of that roll, and a second line connecting the axes of the first and second rolls. The contact angle for the first roll may be greater and/or less than that of the second roll when the conductive element is being compressed between the rolls. For example, where the rolls are vertically aligned, the conductive elements may be fed into the gap between the rolls in a non-horizontal plane.

Alternatively, the contact angle for the first roll may be substantially the same as that of the second roller when the element is just being pulled through the rolls. For example, where the rolls are vertically aligned, the conductive elements may be fed into the gap in a substantially horizontal plane.

The arrangement of the second roll above the first roll allows the conductive elements to be arranged on an upward facing surface of the bottom roll (i.e. the first roll). The bottom roll may be configured to grip the conductive elements due to gravity, which helps guide the conductive elements through the gap.

During the operation of the apparatus, the gap between the first and second rolls may change (i.e. it may periodically increase and decrease) due to the rolls' continual rotation. The maximum gap between first and second rolls (e.g., at the point of greatest separation between the rolls) may be at least 0.3 mm and/or up to 5 mm. Accordingly, the distance between the rolls at their point of greatest separation is such that both rolls do not contact the conductive elements because the thickness of the non-compressed conductive elements (e.g., 0.2 mm) is smaller than the maximum gap between the rolls (e.g., at least 0.3 mm). In an exemplary arrangement, the conductive elements may rest on the lower roll without contacting the upper roll.

The minimum gap between the first and second rolls (e.g., at the narrowest point between the rolls) may be at least 0.05 mm and/or up to 4.75 mm. Accordingly, the gap between the rolls at their narrowest point (e.g., around 0.08 mm) is periodically less than the thickness of the non-compressed conductive elements (e.g., around 0.2 mm), which causes the rolls to periodically compress the height of the conductive elements (e.g., to 0.08 mm) as the rolls rotate. For example, during the periods when the narrowest point is less than the thickness, the portions of conductive elements between the rolls will be compressed, whereas, during the periods when the narrowest point is greater than the thickness, the portions of the conductive elements between the rolls will not be compressed.

In an exemplary embodiment, the maximum distance between the rolls is around 0.5 mm and the minimum distance between the rolls is around 0.08 mm.

Only one of the first and second rolls may be configured to reduce the gap between the first and second rolls. For example, at least one of the first and second rolls may be configured to periodically not apply the compressive force to the plurality of conductive elements. Put another way, the at least one of the first and second roll may be configured to alternate between periodically applying the compressive force and not applying the compressive force.

One of the rolls may be shaped (i.e. dimensioned) to produce an eccentric rotation about its axis, which causes a periodic reduction in the gap between the first and second rolls (e.g. the roll may comprise an elliptical cross-section). In this situation, the other of the rolls may be configured to provide a substantially non-eccentric rotation about its axis (e.g. the other roll may comprise a circular cross-section). As such, the other of the rolls (i.e. the non-eccentric roll) would not contribute to the reduction in the size of the gap between the first and second rolls. When in use, both rolls are configured to exert force upon the conductive elements and would thereby contribute to the reduction in the thickness (e.g., thickness/depth) of the conducive elements.

In embodiments, the first roll may comprise a substantially circular cross-section and the second roll may be configured to periodically reduce the gap between the first and second rolls. By configuring one of the rolls with a circular cross-section, this reduces the complexity and cost of manufacturing the apparatus. In an alternative arrangement, both the first and second rolls may be configured to cause the reduction in the gap between the rolls. For example, each of the rolls may be configured (e.g. shaped) to produce an eccentric rotation about their respective rotation axes, such that they both contribute to the reduction in the size of the gap between the rolls.

At least one of the first and second rolls may comprise a cross-section geometry configured such that, when it rotates, the gap between the first and second rolls periodically reduces in the radial direction. In an embodiment both rolls may have such a geometry. In another embodiment, one roll may have such a geometry whilst the other may have, for example, a circular cross-section. In an embodiment, during use (e.g. whilst one or more rolls rotates), the apparatus holds the first roll (e.g. an axis of rotation of the first roll) in a fixed relationship with the second roll (e.g. an axis of rotation of the second roll). As such, the aforementioned cross-section geometry, when it rotates, causes the gap to alternately reduce and increase, to alternately apply and not apply a compressive force to sequential portions of the conductive elements within the gap.

The at least one of the first and second rolls may comprise an elliptical cross-section. For example, the second roll may be configured with an elliptical cross-section, and the first roll may be configured with a circular cross-section.

The elliptical cross-section may have one axis of symmetry. The elliptical cross-section may have two axes of symmetry. For example, the elliptical cross-section may take the form of a regular ellipse. In an alternative arrangement, the elliptical cross-section may only have one axis of symmetry. For example, the cross-section may comprise an oval shape (e.g. a non-regular circle) which resembles the outline of an egg (e.g. a 2D projection of an egg-shape).

At least one of the first and second rolls may comprise a cross-section shaped as an elliptical segment (e.g. major or minor), such as a circular segment (e.g. major or minor). In embodiments, the at least one of the first and second rolls may comprise a semi-elliptical cross section, such as a semi-circular cross section.

The at least one of the first and second rolls may comprise a first surface and a second surface. The first and second surfaces may be configured to curve outwardly, wherein the first surface has a variable radius of curvature (e.g. like an ellipse) and the second surface has a substantially constant radius of curvature (e.g. like a circle). Such a shape may correspond to an egg-shape in which there is a clearly defined boundary between its broader and narrower ends.

At least one of the first and second rolls may comprise a cross-section having a geometric centre (e.g. the arithmetic mean position of all the points in the shape). At least one of the first and second rolls may be configured with a rotation axis that is misaligned with the geometric centre. The resulting roll may be configured with an off-centred rotation axis. A roll configured in this way may be configured with an eccentric rotation about its rotation axis, even if the roll's cross-section has a non-eccentric shape (e.g. a circle). Accordingly, the roll may be configured such that the roll (i.e. its centre of mass) is physically moved back and forth, with respect to the other roll, to alternately reduce and increase the gap between the two rolls. Such an arrangement may be configured to periodically reduce the gap between the first and second rolls in order to deform successive periodic sections of a conductive element as the roll rotates.

At least one, or each, of the plurality of conductive elements may comprise a section which is to be compressed by the apparatus. This compressed section may be arranged between two sections which are not to be compressed by the apparatus (i.e. non-compressed sections). For example, the electrode assembly may be formed by cutting the plurality of conductive elements to form a plurality of conductive element portions each comprising a compressed section arranged between two non-compressed sections. In this situation, a perimeter of the cross-section of the at least one of the first and second rolls may define a length which corresponds to the combined length of two compressed sections and two non-compressed sections.

In a preferred arrangement of the electrode assembly, the plurality of conductive element portions may comprise only one compressed section arranged between two non-compressed sections. The apparatus may be configured such that each rotation of the roll(s) deforms the conductive elements to produce a sequence of two alternating compressed and non-compressed sections (e.g. compressed, non-compressed, compressed, non-compressed). This may be the case where, for example, one of the rolls comprises an elliptical cross-section.

In order to fabricate the preferred electrode assembly, every other compressed section may be removed (e.g. cut) from the conductive elements during the cutting of conductive elements. For example, a cut may be made at either side of every other compressed section to form a plurality of conductive element portions having a single compressed section arranged between two non-compressed sections. Cutting the conductive elements in this way not only separates the conductive elements into their respective portions, it also removes the additional compressed section. According to the above arrangement, the perimeter of the cross-section of the at least one of the first and second rolls may be greater than the length of the conductive element portions of the final electrode assembly.

In an alternative arrangement, the apparatus may be configured such that each rotation of the roll(s) deforms the conductive elements to produce one compressed section and one non-compressed sections. This is the case where, for example, one of the rolls comprises an egg-shaped cross-section. In this situation, the non-compressed section may be substantially longer than the compressed section, since the non-compressed section substantially corresponds with the combined lengths of both the front surface of the first solar cell and the back surface of the second solar cell.

According to the above arrangement, the preferred electrode assembly can be obtained by performing a single cut substantially in the centre (e.g. in a longitudinal direction) of each of the non-compressed sections. No other cuts are needed because (unlike the previous arrangement) there is no additional compressed section to be removed. According to this arrangement, the perimeter of the cross-section of the at least one of the first and second rolls may be substantially equal to the length of the conductive element portions of the final electrode assembly.

It will be appreciated that the conductive elements may be fed into the gap between the rolls at a speed which is substantially matched to the rotation speed of the rolls, so as to ensure that the correct section of the conductive elements is deformed.

In embodiments, at least one, or each, of the plurality of conductive elements may each comprise a first section for only contacting the front surface of the first solar cell (e.g., it is arranged not to contact the second solar cell), a second section for contacting only the back surface of the second solar cell (e.g., it is arranged to not contact the first solar cell), and a third section for contacting both the front surface of the first solar cell and the back surface of the second solar cell. Each of the at least one conductive elements' third sections may be configured to connect (e.g. mechanically and electrically) between the respective first and second sections. In this situation, a perimeter of the cross-section of the at least one of the first and second rolls may define a length which corresponds to the combined length of the first, second and third sections of the plurality of conductive elements. Accordingly, the third section may define the compressed section of the previously described example.

Prior to being deformed by the apparatus, the at least one, or each, of the conductive elements may comprise a substantially constant cross-section along its length. Each conductive element may be configured so as not to comprise any axial twists or turns along its length.

Once the conductive elements have been deformed by the apparatus, a portion of the at least one, or each, of the conductive element(s) may comprise two substantially planar surfaces arranged on opposite sides of the conductive element. A first surface may define a substantially planar surface which faces the front surface of the first solar cell, and a second surface may define a substantially planar surface which faces the back surface of the second solar cell. In embodiments, the first and/or second surface(s) may be configured to be substantially parallel to the respective front and back surface(s) of the first and second solar cell(s).

In an exemplary arrangement, the compressed section of the conductive element may have an obround profile (i.e. an obround shaped cross-section). The non-compressed section(s) of the conductive element may retain a substantially elliptical profile (i.e. an ellipse shaped cross-section). For example, the non-compressed section(s) may comprise a circular cross-section.

According to a second aspect of the invention there is provided a method of manufacturing an electrode assembly for connecting a front surface of a first solar cell to a back surface of a second solar cell. The method comprises providing a plurality of conductive elements, arranging the plurality of conductive elements in a common plane such that they lie substantially parallel to one another in a longitudinal direction, and are substantially spaced apart in a transverse direction. The method further comprises periodically reducing the height of a section of the plurality of conductive elements.

The method of reducing the height of the section of the plurality of conductive elements comprises: providing a first roll (e.g. roller) and a second roll (e.g. roller) which are spaced apart to define a gap therebetween for receiving the plurality of conductive elements; feeding the plurality of conductive elements at least partially through the gap between the first and second rolls; and periodically reducing the gap between the first and second rolls, when at least one of the first and second rolls rotate to periodically apply a compressive force to the plurality of conductive elements arranged in the gap.

The method may comprise periodically increasing the gap between the first and second rolls, when the at least one of the first and second rolls rotate, to periodically not apply compressive force to the plurality of conductive elements. Accordingly, the periodic sections of the conductive elements which are arranged either side of the compressed sections remain undeformed (i.e. non-compressed).

The method may comprise arranging an electrically insulating and optically transparent film onto a non-compressed section of the plurality of conductive elements. The film ensures that each of the conductive elements remains in the same position relative to the other conductive elements (e.g. in a transverse and/or longitudinal direction(s)) during the deforming process.

The method may comprise arranging the electrically insulating and optically transparent film onto the conductive elements prior to feeding the conductive elements at least partially through the gap between the first and second rolls. By applying the film to the conductive elements before feeding them through the gap, the film further enhances the stability of the conductive elements during the deforming process.

The electrically insulating and optically transparent film may be arranged so as not to not cover compressed section(s) of the plurality of conductive elements. By not arranging the film on the compressed section(s), this ensures that the foil doesn't get in the way of the deforming process, and it allows the conductive elements to sit flush between the respective surfaces of the first and second solar cells, when the electrode assembly is arranged in the solar cell assembly.

The method may comprise cutting the plurality of conductive elements to define a plurality of conductive element portions. Each of the conductive element portions may comprise a compressed section arranged between two non-compressed sections. In embodiments, each of the conductive element portions may comprise a first section, a second section and a third interconnecting section, as described above.

The method step of cutting the conductive elements may occur after the method step of reducing the height of the compressed section. By deforming the conductive elements before they are cut ensures the stability of the conductive elements during the deforming process.

According to a third aspect of the invention there is provided a method of manufacturing a solar cell assembly. The method comprises manufacturing an electrode assembly according to any one of the preceding statements. The method further comprises providing a first solar cell and a second solar cell.

The solar cells may each comprise a back (e.g. backmost) surface and a front (e.g. frontmost) surface being opposite the back surface. Accordingly, the method may comprise arranging a section of the electrode assembly onto the back surface of the second solar cell to define a back connector. The method may further comprise arranging another section of the electrode assembly onto the front surface of the first solar cell to define a front connector.

Each of the plurality of conductive elements may comprise a first section for contacting only the front surface of the first solar cell, a second section for contacting only the back surface of the second solar cell, and a third section for contacting both the front surface of the first solar cell and the back surface of the second solar cell. Each of the at least one conductive elements' third sections may be configured to connect (e.g. mechanically and electrically) between the respective first and second sections.

The method may include arranging the second solar cell such that its back surface is facing in a substantially upward direction and/or arranging the second solar cell so that its front surface is facing in a substantially downward direction.

The method may comprises overlaying the second section of the plurality of conductive elements of the electrode assembly onto the back surface of the second solar cell.

The method may include overlaying the front surface of the first solar cell onto the first section of the plurality of conductive elements such that the front surface of the first solar cell partially overlaps the back surface of the second solar cell. This method step may also include overlaying the front surface of the first solar cell such that the third section of the plurality of conductive elements is arranged between the overlapping parts of the front surface of the first solar cell and the back surface of the second solar cell.

The method may further comprise connecting the first and second sections of the plurality of conductive elements to the respective front and back surfaces of the first and second solar cells.

The at least one, or each, of the plurality of conductive elements may comprise a first surface and a second surface, wherein the second surface is arranged on a substantially opposite side of the conductive element to the first surface. When in use, the first surface may define a front surface (i.e. a front facing surface) of the conductive element and the second surface may define a back surface (i.e. a back facing surface) of the conductive element.

The method may further comprise connecting (e.g. electrically and/or mechanically) the first surface (i.e. the front surface) of the at least one conductive element onto the back surface of the second solar cell. The method may further comprise connecting (e.g. electrically and/or mechanically) the second surface (i.e. the back surface) of the at least one conductive element onto the front surface of the first solar cell.

The method may comprise overlaying the front surface of the first solar cell onto the first section of the electrode assembly such that the first surface of the at least one conductive element is arranged in contact with the front surface.

At least one or each of the plurality of conductive elements may comprise a coating which is configured, when in use, to solder the conductive elements to the respective surfaces of the solar cells upon which they are overlaid.

The method may comprise applying heat and/or pressure to (e.g. soldering) the first section of the conductive elements (i.e. of the front connector) to melt at least a portion of the coating. For example, the melted coating which is arranged on the first surface of the conductive element (i.e. the surface which faces the back surface of the second solar cell) may be configured to form an ohmic contact with the conductive surface of the second solar cell (e.g. the finger electrode), upon which the conductive element is overlaid.

The coatings of the conductive elements may be comprised of materials which have melting points which are lower than the materials from which the conductive elements are formed. The method may comprise applying heat and/or pressure (e.g. soldering) to the second section of the conductive elements (i.e. of the back connector) to melt at least a portion of the coating.

The melted coating which is arranged on the second surface of the conductive element (i.e. the surface which faces the back surface of the second solar cell) may be configured to form an ohmic contact with the conductive surface of the second solar cell (e.g. the finger electrode), upon which the conductive element is overlaid.

The method may comprise first attaching one of the front and back connectors to the respective first and second solar cells, then attaching the other of the front and back connectors to the other of the respective first and second solar cells. The coatings of the conductive elements of the front and back connectors may be connected to their respective surfaces of the first and second solar cells separately, or during the same process.

In situations where the electrode assembly comprises a film (e.g. an insulating and/or optically transparent film), then the method may further comprise attaching the film to the conductive elements (e.g. to form an electrode assembly according to an exemplary arrangement). The method may comprise attaching the film to the conductive elements prior to overlaying, and/or attaching, the conductive elements to the solar cells. The method may comprise heating and/or applying pressure to the film (e.g. laminating) to adhere the film to the conductive elements.

In situations where a first portion of the plurality of conductive elements is arranged on a first film portion and/or a second section of the plurality of conductive elements is arranged on a second film portion, the first and/or second film portions may be attached to the respective first and/or second sections of the conductive elements.

The method may further comprise arranging (e.g. depositing) a plurality of finger electrodes on at least one, or each, of the front and back surfaces of the first and second solar cells. It will be understood that the method of arranging the finger electrodes may be performed prior to connecting the electrode assembly to the solar cells. The finger electrodes may be formed using a printed material, which enables it to be conveniently deposited onto the surfaces of the solar cells. The printed material may be formed using a printable precursor, such as a conductive paste which may comprise a metal powder (e.g. Ag, Al, Au powder) suspended in a solvent. The printable precursor/conductive paste may be dried (e.g., set or cured) to form the printed finger electrodes. Alternatively, the finger electrodes may be deposited by various other methods including evaporation, plating, printing etc. The front and back finger electrodes may be deposited simultaneously (i.e. using a single deposition process) or they be deposited separately.

According to a fourth aspect of the invention there is provided an electrode assembly for connecting a front surface of a first solar cell to a back surface of a second solar cell. The electrode assembly may be manufactured according to the method of any one of preceding statements. As described above, the plurality of conductive elements may each comprise a first section for contacting the front surface of the first solar cell, a second section for contacting the back surface of the second solar cell, and a third section configured to connect (e.g. directly or indirectly) the first section to the second section. The thickness (e.g. the height) of the plurality of conductive elements may reduce progressively in a lengthways direction along the plurality of conductive elements from the first section towards the third section and/or from the second section towards the third section. The conductive elements (e.g. the first, second and/or third sections) may be configured with a curved surface when viewed in an axial section of the conductive element. The conductive elements (e.g. the first, second and/or third sections) may be configured with a curved upper and lower surface. For example, the conductive elements (e.g. the first, second and/or third sections) comprise opposing concave surfaces. In an embodiment, the first and second sections each comprise a progressive reduction in thickness, whereas the third section comprises a constant thickness, wherein the constant thickness of the third section matches the smallest thicknesses of the first and second sections. The progressively reduced thickness defines a transition between the non-compressed sections (e.g., the first and second sections) and the compressed sections (e.g. the third sections) of the conductive elements. As such, this transition region may be configured such that it combines the beneficial scattering properties of non-compressed conductive elements with the packaging advantages of compressed conductive elements.

The first section of each of the conductive elements may, together, define the front connector of the electrode assembly. Similarly, the second sections may define the back connector of the electrode assembly. The third sections may define an interconnector configured to electrically couple together the respective first and second sections of the conductive elements (i.e. the front and back connectors of the electrode assembly). At least one, or each, of the third sections of the plurality of conductive elements may extend between the respective first and second sections of the plurality of conductive elements.

Each of the conductive elements may comprise an elongate form, such as a wire or wire portion. The at least one, or each, conductive element may comprise a single integrally formed element (e.g. a wire). Configuring the conductive elements in this way removes the need to provide separate connections (such as copper ribbons) between overlapping solar cells, which thereby reduces the number and complexity of manufacturing steps required to fabricate the solar cell assembly.

Each of the conductive elements may comprise a width, an axial length, and a depth. Each of the conductive elements may be configured such that its axial length is substantially greater than its width and/or depth. The width and axial length of the conductive elements may be measured in perpendicular directions aligned with a plane of the surface of the solar cell upon which the conductive elements are arranged (e.g. the front or back surface of the solar cell). The depth (e.g. thickness) may be measured in a direction which is perpendicular to the same plane of the solar cell.

In embodiments, the at least one, or each, conductive element's first and/or second sections (i.e. the non-compressed sections) may be configured with a width of at least 0.2 mm and/or up to 0.4 mm, at its widest point. The length of the at least one, or each, conductive element's first and/or second sections may be at least 5 mm and/or up to a length which corresponds to the length of the solar cell. The depth of the at least one, or each, conductive element's first and/or second sections may be at least 0.2 mm and/or up to 0.4 mm, at its deepest point. For example, at least one, or each, of the conductive element's first and/or second sections may have a thickness of around 0.2 mm.

In embodiments, the at least one, or each, conductive element's third section (i.e. the compressed section) may be configured with a width that is between 120% and 150% of the width of at least one of the non-compressed regions, at its widest point. For example, a conductive element having first and/or second sections comprising a width of 0.2 mm, the third section may have a width of 0.24 mm, at its widest point. The length of the at least one, or each, conductive element's third section may be at least 5 mm and/or up to a length which corresponds to the length of the solar cell. The depth of the at least one, or each, conductive element's third section may be between 25% and 60%, optionally at least 40%, of the depth of at least one of the non-compressed regions, at its deepest point. For example, a conductive element having first and/or second section(s) comprising a depth of 0.2 mm, at its deepest point, may comprise a third section having a depth of 0.05 mm, at its deepest point. Alternatively, the rolls may be configured to reduce the height by 40% in which case the thickness of the compressed third section may be 0.08 mm.

It will be understood that the terms ‘conductive’ and ‘insulating’ as used herein, are expressly intended to mean electrically conductive and electrically insulating, respectively. The meaning of these terms will be particularly apparent in view of the technical context of the disclosure, being that of photovoltaic solar cell devices. It will also be understood that the term ‘ohmic contact’ is intended to mean a non-rectifying electrical junction (i.e. a junction between two conductors which exhibits a substantially linear current-voltage (I-V) characteristic).

The conductive element(s) may be formed of an electrically conductive material, such as a metallic or metallic alloy material, which may include at least one of Ag, Al, Au and Cu.

According to an exemplary arrangement, each of the plurality of conductive elements may comprise a coating (not shown) which is configured, when in use, to solder the conductive elements to the respective surfaces of the solar cells upon which they are overlaid.

The coating (i.e. the solderable coating) may comprise an electrically conductive material having a melting point which is lower than that of the conductive element. The coating may comprise a metal alloy formed of at least two or more components. The coating alloy may be at least one of a lead based, tin based and bismuth-based alloy. The coating may comprise a 2-phase, 3-phase, or more complex metal alloy. The coating may be formed of a metal alloy comprising at least one of Ag, Bi, Cd, Ga, In, Pb, Sn, Ti, etc. The coating may also comprise an electrically conductive material which is formed of metallic or alloy particles embedded within an organic matrix.

The coating may be configured to substantially cover at least one, or each, of the first and second surfaces of the at least one conductive element(s). The coating may be configured to substantially cover each conductive element's first and second surfaces. For example, in embodiments where the conductive element(s) comprise a third surface, and/or a fourth surface, which separate the first and second surfaces, then at least one, or each, of the third and/or fourth surfaces may be at least partially coated by the coating. Each conductive element may be completely coated by the coating. In embodiments, the coating may be absent from a portion of the first surface and/or the second surface. In embodiments, the coating may be absent from at least a portion of the third surface and/or the fourth surface.

At least one, or each, of the plurality of conductive elements may be arranged in and/or on a film. The film may be configured to be insulating and/or optically transparent. The film may be configured to provide adhesion between the solar cell and the conductive element so that the conductive element is correctly spaced on the solar cell. In this way, the film enables the conductive elements to be correctly aligned with the solar cell. The film may provide a mechanical connection between the conductive element and the solar cell. In an exemplary arrangement, the film may not cover all the respective front and/or back surface(s) of the solar cell. For example, the film may not extend completely across at least one dimension (e.g. the length and/or width) of the solar cell. Alternatively, the film may cover the entire surface of the solar cell, for example, the film may extend completely across the width and/or length of the solar cell.

The film may be configured such that at least a portion of at least one of the first and second surfaces of the at least one conductive element is exposed from the film to form an ohmic contact with the respective front and back surfaces of the first and second solar cells. For example, at least a portion of the conductive element's first surface may be exposed from the film and/or at least a portion of the conductive element's second surface may be exposed from the film. The film may comprise a thickness of at least 50 μm and/or up to 100 μm, which may be less than the thickness of conductive elements on to which the film is overlaid, so that the conductive elements may be exposed from the film.

As described above, the conductive elements of the front and back connectors may define, respectively, first and second sections of the plurality of conductive elements. The first section of the plurality of conductive elements may be arranged in or on a first film (e.g. insulating and/or optically transparent film). The second section of the plurality of conductive elements may be arranged in or on a second film (e.g. insulating and/or optically transparent film).

When in use, the first film of the front connector may define a front film (i.e. a front-film portion) of the electrode assembly. Similarly, the second film of the back connector may define a back film (i.e. a back-film portion) of the electrode assembly. The front film may be configured such that at least a portion of the back surface of the front connector's conductive elements is exposed. The back film may be configured such that at least a portion of the front surface of the back connector's conductive elements is exposed.

As described above, the third section of the plurality of conductive elements may be configured to connect the first and second portions of the plurality of conductive elements. Accordingly, the third section may be configured to be arranged between the overlapping surfaces of the first and second solar cells. The third section may be configured such that the conductive elements in this section are not arranged in (or on) a film (i.e. in contrast to the first and second sections).

At least one, or each, of the conductive elements may be disposed on a surface of the respective first and second films. Alternatively, or in addition, at least one of the conductive elements may be arranged at least partially within the film. In this way, the at least one conductive element may be embedded within the film such that a surface of the conductive element protrudes from the surface of the film.

The film (e.g. the front and/or back films) may be formed of a polymer material having a high ductility, good insulating characteristics, optical transparency and thermal stability, resistance to shrinkage. Exemplary polymer materials may comprise acetate, epoxy resin, fluororesin, polyamide resin, polysulfone, rayon, polyolefin, plastilene, rayonext, polyethylene terephthalate (PET), polyvinyl fluoride film and modified ethylene tetrafluoroethylene, etc. In an embodiment, at least one of the first and second film consist of a single layer of material; however, in some other embodiments, at least one of the first and second films comprise two or more layers wherein two or more of these layers may include different materials and/or material characteristics.

The surface of the film facing the conductive elements may be coated with a transparent adhesive. During fabrication of the solar cell assembly, heat and/or pressure may be applied to the film so that the adhesive softens to enable adherence of the film to the conductive elements due to an application of force. In this way, the wires may be at least partially embedded in the adhesive. In embodiments, the conductive elements may be partially embedded in the adhesive but not actually contact the film. The first and/or second film(s) may be configured to provide structural support for the conductive elements when the plurality of conductive elements are being handled, prior to being arranged onto the solar cell(s).

When the front and back connectors are assembled with their respective first and second solar cells, the associated film may deform to conform to the shape of the conductive elements sandwiched between the film and the solar cell. In other words, the surface of the film may be substantially planar in non-element contacting regions, and form ridges/protuberances over the conductive elements in the element contacting regions. In this way, each (e.g. longitudinal) conductive element contacting region of the film may have a non-planar (e.g. transverse) profile.

The film of the front connector may have a back surface (i.e. facing towards the solar cell), and a front surface (i.e. facing away from the solar cell) opposite the back surface. At least one conductive element of the first portion of the plurality of conductive elements may be disposed on the back surface of the front film.

The film of the back connector may have a front surface (i.e. facing towards the solar cell), and a back surface (i.e. facing away from the solar cell) opposite the front surface. At least one conductive element of the second portion of the plurality of conductive elements may be disposed on the front surface of the back film.

According to a fifth aspect of the invention there is provided a solar cell assembly comprising a first solar cell, a second solar cell and an electrode assembly according to any one of preceding statements. The plurality of conductive elements may be configured to electrically couple a front surface of the first solar cell with a back surface of the second solar cell.

The solar cell assembly may be manufactured according to the method of any one of preceding statements. The plurality of conductive elements may be configured to electrically couple a front surface of the first solar cell with a back surface of the second solar cell. The back surface of the second solar cell may be configured to at least partially overlap the front surface of the first solar cell. The third section of the plurality of conductive elements may be arranged between the partially overlapping surfaces of the first and second solar cells. The deformed third section of the conductive elements is thereby configured to spread the load between the partially overlapping first and second solar cells. The resulting electrode assembly is able to provide a stronger mechanical connection between the solar cells in the overlapping region.

The conductive element(s) may be configured to form an ohmic contact with an electrically conductive surface (e.g. an electrically conductive portion of a surface) of the solar cells. Each of the solar cells may comprise a layered structure which includes a photovoltaic element, as would be understood by the skilled person. The conductive surface(s) may comprise one or more finger electrodes that are arranged on (e.g. printed on) the solar cell's front and back surfaces to conduct away charge carriers that are generated by the layered structure.

Each of the first and second solar cells may comprise a length, a width, and a depth. The length of the solar cell may be less than its width, and the depth may be less than both the width and the length. The longitudinal and transverse directions across the front and back surfaces of the solar cell may be parallel with the length and width directions of the solar cell, respectively. Hence, the plurality of conductive elements may be configured to extend across the length of the solar cell, and to be spaced along its width.

Each of the conductive elements may be configured to extend lengthwise relative to the surface of the solar cell upon which it is overlaid, in a longitudinal direction. The conductive elements may be spaced apart in a transverse direction relative to the solar cell surface to define longitudinal-extending spaces between the conductive elements. The conductive elements may be parallel or substantially parallel to one another. The conductive elements may be equally or substantially equally spaced in the transverse direction. Accordingly, the plurality of conductive elements may form an array of parallel, transversely spaced (e.g. equally spaced) conductive elements.

The electrode assembly may be configured to form an electrical connection with a conductive surface (or a conductive portion of a surface) of the first and second solar cells. As described above, the conductive elements of the electrode assembly are configured to optimise the optoelectronic properties of the front and/or back connectors, e.g. their electric current collection and solar cell shading characteristics.

Each of the solar cells' conductive surface(s) may comprise a plurality of finger electrodes which extend across the respective solar cell surfaces. The finger electrodes may be formed using a printed material, which enables them to be conveniently deposited onto the surfaces of the solar cells.

Each finger electrode of the pluralities of front and/or back finger electrodes may be configured with an axial length which is substantially greater than its width. Both the width and axial length of the finger electrode may be measured in perpendicular directions in the plane of the respective surface of the solar cell. The finger electrodes may extend in a transverse direction which is parallel with the width direction of the solar cell.

The finger electrodes within each of the pluralities of front and/or back finger electrodes may be spaced apart across the respective surface to define transversely extending spaces between the finger electrodes. The finger electrodes may be spaced apart in a longitudinal direction which is substantially parallel with the length direction of the solar cell. The finger electrodes in each plurality may be substantially parallel to one another.

The axial length of at least one finger electrode of the plurality of back finger electrodes may be substantially misaligned (e.g. substantially non-parallel or substantially perpendicular) with the axial length of at least one of the conductive elements of the electrode assembly, which is overlaid upon it. Accordingly, the conductive elements of the electrode assembly may be configured to extend across the surface of the solar cell to form an ohmic contact with each of the plurality of finger electrodes. In this way, the conductive elements can be conveniently arranged to optimise the charge collection from the surface of the solar cell.

The solar cell of the solar cell assembly may comprise a plurality of layers, or elements, including a photovoltaic element, wherein at least one of the plurality of layers is formed of a semiconductor material. The photovoltaic element (or layer) may be formed of a crystalline silicon wafer. It will be appreciated that the solar cell may be configured to define any type of solar cell structure. For example, the solar cell may define a heterojunction type solar cell. Alternatively, the solar cell may define a tandem junction solar cell.

The surface(s) of the solar cell may be textured to form a textured surface corresponding to an uneven surface or having uneven characteristics. In this instance, an amount of light incident on the solar cell increases because of the textured surface of the solar cell, and thus the efficiency of the solar cell is improved.

The solar module may comprise a frame in which to house the plurality of solar cell assemblies. The frame may comprise a front plate and a back plate which are arranged, respectively, on the front and back sides of the plurality of solar cell assemblies. At least one or each of the front and back plates may be formed of glass (e.g. a glass sheet). The solar module may comprise an encapsulant which may be configured to provide adhesion between the front and back plates and the plurality of solar cell assemblies. In this way, the encapsulant may be arranged between the glass sheet of the solar module, and an insulating optically transparent film of one of the pluralities of solar cell assemblies. Also, the encapsulant may be arranged between the back sheet of the solar module, and an insulating optically transparent film of one of the pluralities of solar cell assemblies. The encapsulant may be configured to prevent the ingress of moisture into the solar module. Accordingly, the encapsulant may be formed of ethylene vinyl acetate (EVA), or any other suitably moisture resistant material.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DRAWINGS

Embodiments will now be described by way of example only, with reference to the Figures, in which:

FIG. 1 is a close-up sectional side view of a solar module including a solar cell assembly, the solar cell assembly comprising a first solar cell and a second solar cell arranged in an overlapping configuration;

FIG. 2 is a plan view of the top of the first and second solar cells, as shown in FIG. 1 the first and second solar cells being coupled together by an electrode assembly;

FIG. 3 is a close-up transverse sectional view taken through the first solar cell along line A-A, as shown in FIG. 2;

FIG. 4 is a close-up transverse sectional view taken through the first and second solar cells along line B-B, as shown in FIG. 2;

FIG. 5 is a close-up longitudinal sectional view taken through the first and second solar cells along line C-C, as shown in FIGS. 2 and 4;

FIG. 6 is a perspective view of an apparatus for flattening a section of the electrode assembly shown in FIGS. 2 to 5;

FIG. 7 is a side view of the apparatus shown in FIG. 6;

FIGS. 8 to 12 are sectional views of a first and a second roll of the apparatus shown in FIGS. 6 and 7, showing the different stages of a method of flattening a section of the electrode assembly;

FIGS. 13 to 17 are sectional views of alternative rolls suitable for use in the flattening apparatus shown in FIGS. 6 and 7; and

FIG. 18 is a flowchart illustrating a method of manufacturing the electrode assembly.

### DETAILED DESCRIPTION

Aspects and embodiments of the present disclosure will now be discussed with reference to the accompanying figures. Further aspects and embodiments will be apparent to those skilled in the art.

In the drawings, the thickness of layers, films, elements etc., are exaggerated for clarity. Furthermore, it will be understood that when an element such as a layer, film, region, or substrate is referred to as being “on” another element, it can be directly on the other element or intervening elements may also be present. In contrast, when an element is referred to as being “directly on” another element, there are no intervening elements present.

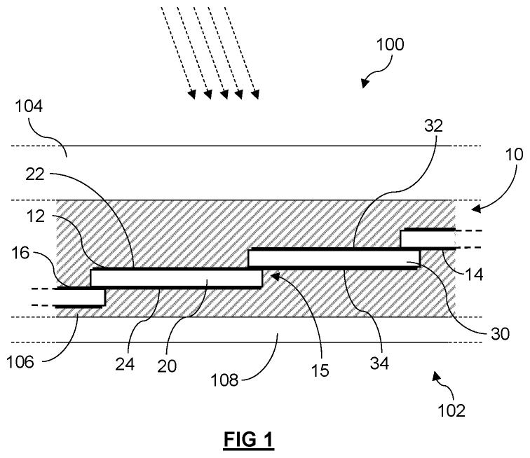

FIG. 1 shows a solar cell assembly 10 according to the present invention, which is arranged within a support assembly 102 of a solar module 100 (e.g. a solar panel). The solar cell assembly 10 includes a first solar cell 20, a second solar cell 30 and an electrode assembly 12 which is arranged to electrically couple a front surface 22 of the first solar cell 20 to a back surface 34 of the second solar cell 30.

The front surface 22 of the first solar cell 20 is partially overlapped by the back surface 34 of the second solar cell 30 to define an overlapping region 15 of the solar cell assembly 10. The electrode assembly 12 extends along the front surface 22 of the first solar cell 20, through the overlapping region 15 and then further extends along the back surface 34 of the second solar cell 30.

The electrode assembly 12 is configured to reduce the build-up of stress at the overlapping region 15 between the solar cells 20, 30, as will be described in more detail below. Also, the electrode assembly 12 is arranged to provide an improved electrical pathway between the first and second solar cells 20, 30, whilst also enhancing the light scattering and absorption conditions at the front surface 22 of the first solar cell 20.

The solar cell assembly 10 is one of a plurality of solar cell assemblies which are arranged within the support assembly 102. For example, a front surface 32 of the second solar cell 30 is electrically coupled to the back surface of a third solar cell by a second electrode assembly 14. Also, a third electrode assembly 16 is provided to couple a back surface 24 of the first solar cell 20 to the front surface of a fourth solar cell.

It will be understood, for example, that the second and third solar cells in this arrangement are electrically coupled together by the second electrode assembly 14 to define a second solar cell assembly. The plurality of solar cells 20, 30 are thereby coupled together by the electrode assemblies 12, 14, 16 to define a single string.

A front plate 104 of the support assembly 102 comprises a transparent (e.g. glass) sheet which is configured to allow light to pass through into a central chamber 106 in which the solar cell assembly 10 is mounted. The arrows at the top of FIG. 1 show the direction of the solar radiation which is incident upon the solar cell assembly 10.

A back plate 108 of the support assembly 102 is arranged to enclose the solar cell assembly 10 within the central chamber 106. The back plate 108 comprises a reflective sheet which is configured to reflect any light which is incident upon its front surface (i.e. front facing surface), back towards the solar cell assembly 10. The central chamber 106 is filled with an encapsulating material (the shaded area shown in FIG. 1) which prevents ingress of external liquid or gaseous entrants.

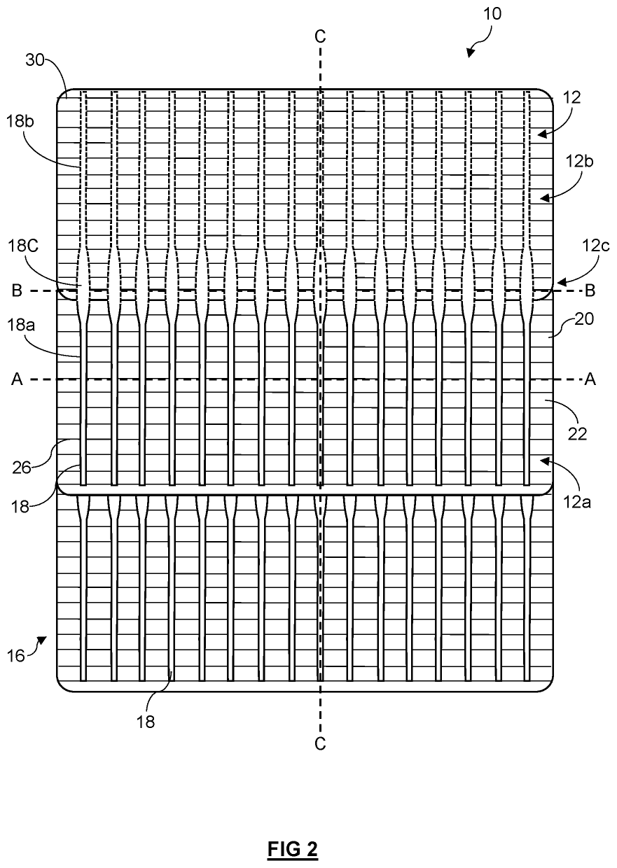

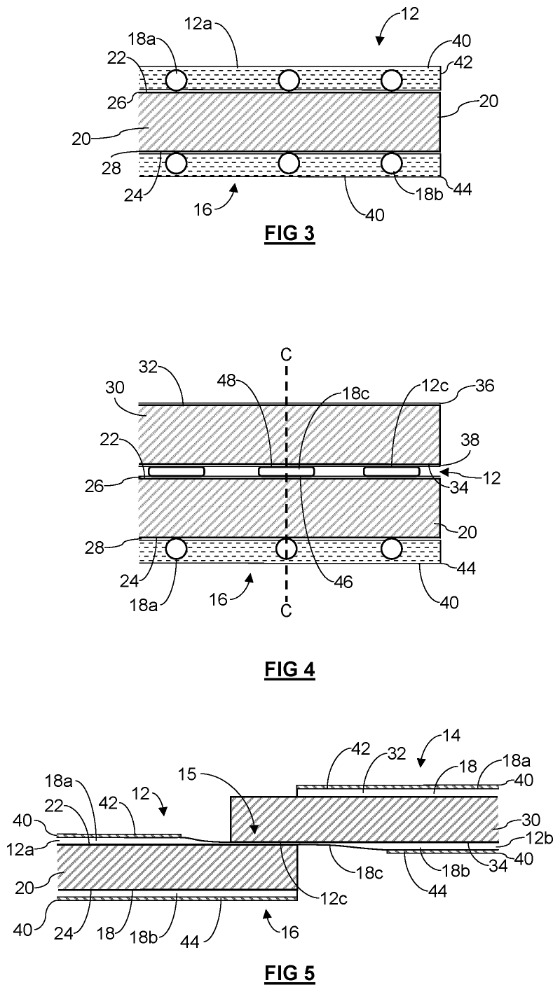

Further aspects of the solar cell assembly 10 will now be described with reference to FIGS. 2 to 5. In particular, FIG. 2 shows a top (front) view of the first and second solar cells 20, 30. FIG. 3 shows a close-up transverse sectional view taken through the first solar cell 20 along line A-A, as shown in FIG. 2. FIG. 4 shows an alternative close-up transverse sectional view taken through the first and second solar cells 20, 30 along line B-B, as shown in FIG. 2. Further, FIG. 5 shows a close-up longitudinal sectional view taken through the first and second solar cells 20, 30 along a portion of line C-C, as shown in FIGS. 2 and 4.

Each of the solar cells 20, 30 has a length which is the vertical dimension of FIG. 2, and a width which is the horizontal dimension of FIG. 2. The first and second solar cells 20, 30 are arranged in separate parallel transverse planes (as shown in FIG. 1) such that their widthwise and lengthwise dimensions lie in parallel with each other. Each of the front surfaces 22, 32 of the respective solar cells define a surface on which light is incident when the solar cell assembly 10 is in use. The back surfaces 24, 34 each define a surface which is opposite to the respective front surface 22, 32, as is most clearly shown in FIG. 1.

Each solar cell 20, 30 includes a layered structure (not shown) arranged between its respective front and back surfaces. The layered structure is a multi-layer semiconductor assembly which includes a photovoltaic element (or layer) which is configured to generate electrical charge carriers from the absorption of incident radiation.

The first solar cell 20 includes a first plurality of finger electrodes 26 arranged on its front surface 22 (i.e. front finger electrodes), and a second plurality of finger electrodes 28 arranged on its back surface 24 (i.e. back finger electrodes). Similarly, the second solar cell 30 includes a first plurality of finger electrodes 36 arranged on its front surface 32, and a second plurality of finger electrodes 38 arranged on its back surface 34. The finger electrodes 26, 36, 28, 38 are each configured to conduct away the electrical charge carriers generated by the respective solar cells 20, 30.

The pluralities of front and back finger electrodes 26, 28, 36, 38 are arranged to extend across the solar cells 20, 30 in the transverse direction (the horizontal direction in FIG. 2) and are equally spaced apart in the longitudinal direction (the vertical direction in FIG. 2). The dimensions of each finger electrode 26, 28, 36, 38 are substantially the same as that of every other finger electrode 26, 28, 36, 38.

Each of the finger electrodes 26, 28, 36, 38 is aligned in parallel with the other finger electrodes arranged on the same solar cell surface. Also, each finger electrode is aligned in parallel with a corresponding finger electrode on the opposite side of the solar cell.

As shown in FIG. 2, each of the pluralities of front and back finger electrodes 26, 28, 36, 38 comprises fourteen finger electrodes. However, it is to be understood that in some other embodiments, the number of front and back finger electrodes 26, 28, 36, 38 may be different, without departing from the scope of the present invention.

The finger electrodes 26, 28, 36, 38 are formed of an electrically conductive material, which is formed of a metallic alloy comprising Ag. The electrically conductive material is a printed material, which enables the finger electrodes to be conveniently deposited onto the respective surfaces of the solar cells.

The electrode assembly 12 comprises a plurality of conductive elements 18 (or conductive element portions) which extend in a lengthwise direction (the vertical dimension in FIG. 2) across the solar cells 20, 30.

Considering FIG. 2, the part of the electrode assembly 12 which is arranged on the bottom surface 34 of the second solar cell 34 is illustrated by dashed lines to signify that parts of the conductive elements 18 are concealed from view by the second solar cell 30. When in use, this part of the electrode assembly 14 would not be visible (i.e. as is the case with the corresponding part of the third electrode assembly 16, which is concealed by the first solar cell 20).

Each of the conductive elements 18 includes a first section 18a arranged to contact the front surface 22 of the first solar cell 20, a second section 18b configured to contact the back surface 34 of the second solar cell 30, and a third section 18c which electrically couples the first and second sections together. Accordingly, the third sections 18c are at least partially arranged between the overlapping front and back surfaces 22, 34 of the respective first and second solar cells 20, 30 (i.e. in the overlapping region 15), as is most clearly shown in FIG. 5.

The conductive elements 18 of the first and second sections 18a, 18b are arranged within an electrically insulating and optically transparent film 40, as shown most clearly in FIG. 3. By contrast, the third sections 18c are free from any film, or foil, as is shown in FIG. 5.

Together the first sections 18a define a front connecting portion 12a (i.e. a front connector) of the electrode assembly 12. Similarly, the second sections 18b define a back connecting portion 12b (i.e. a back connector), of the electrode assembly 12, and the third sections 18c define a third portion 12c configured to electrically couple together the respective first and second portions 12a, 12b (i.e. an interconnecting portion).

The conductive elements 18 each have an integral elongate form, such as a wire, which is formed of an electrically conductive material. For example, the conductive elements 18 comprise a metallic alloy material, which includes at least one of Ag, Al, Au and Cu.

The first and second sections 18a, 18b of the conductive elements 18 are configured to form an ohmic contact with the finger electrodes 26, 38 arranged on the front and back surfaces 22, 34 of the first and second solar cells 20, 30, respectively. The conductive elements 18 are formed of an electrically conductive material such that they are configured to allow electrical charge carriers to flow between the conductive elements 18 and the finger electrodes 26, 38 on the front and back surfaces 22, 34 of the first and second solar cells 20, 30.

During operation of the solar module 100, the conductive elements 18 collect charge carriers from the front finger electrodes 26 of the first solar cell 20 and transport them to the back-finger electrodes 38 of the second solar cell 30. Accordingly, each of the conductive elements 18 defines a current collector of the electrode assembly 12.

According to an exemplary arrangement, each of the plurality of conductive elements 18 comprises a coating (not shown) which is configured, when in use, to solder the first and second sections 18a, 18b to the respective surfaces of the solar cells 20, 30 upon which they are overlaid. The coating is formed from an electrically conductive material having a melting point which is lower than that of the conductive element 18. The coating comprises a metal alloy formed of at least two or more components, such as a lead based, tin based and bismuth-based alloy. Alternatively, the coating may comprise a 2-phase, 3-phase, or more complex metal alloy, as would be understood by the skilled person.

The number of conductive elements 18 of the electrode assembly 12 is between 4 and 20. According to the embodiment described herein the first electrode assembly 12 has sixteen conductive elements 18, as shown in FIG. 2. However, it will be appreciated that, in some other embodiments, a different number of conductive elements may be present, without departing from the scope of the present invention.

The first, second and third sections 18a, 18b, 18c of the plurality of conductive elements 18 are parallel and extend lengthwise relative to the front and back surfaces 22, 34 of the solar cells, in a longitudinal direction (the vertical direction in FIG. 2). The conductive elements 18 are also equally spaced apart in a transverse direction relative to the front and back surfaces 22, 34 (the horizontal direction in FIG. 2) to define longitudinal-extending spaces between the conductive elements 18.

Each of the first sections 18a are parallel with the corresponding second sections 18b of the same electrode assembly 12. Accordingly, each of the first and second sections 18a, 18b defines an array of parallel, transversely spaced conductive elements 18. Also, the first sections 18a of the first electrode assembly 12 are parallel with the second sections 18b of the third electrode assembly 16 with the first solar cell 20 interposed between, as shown in FIG. 5. Similarly, the second sections 18b of the first electrode assembly 12 are parallel with the first sections 18a of the second electrode assembly 14, with the second solar cell 30 interposed between.

According to the above described arrangement, it will be understood that the first and second sections 18a, 18b of the plurality of conductive elements 18 are arranged perpendicular to the pluralities of front and back finger electrodes 26, 38, as shown in FIG. 2.

Each of the conductive elements 18 comprises a width, length, and depth that is substantially the same as every other conductive element 18. The length of each conductive element 18 defines an axial length which is substantially greater than its width and depth. The first and second sections 18a, 18b are configured with a substantially circular cross-section, as is most clearly shown in FIGS. 3 and 4. By contrast, the third sections 18c are each configured with a substantially obround, or rectangular, shaped cross-section, as is most clearly shown in FIG. 4.

The cross-sectional shape of the third section 18c is configured with a height (in the vertical direction shown in FIG. 4) which is substantially smaller than its width (in the horizontal direction shown in FIG. 4). The flattened, or compressed, shape of the third section 18c defines a substantially planar portion of the front and back surfaces 48, 46 of the conductive elements 18. The planar front and back surfaces provide a greater contact area with the respective surfaces 22, 34 of the first and second solar cells 20, 30 (i.e. compared with the curved surface of the first and second sections 18a, 18b). For example, when the electrode assembly 12 is arranged between the first and second solar cells 20, 30 the back surface 46 of the third section 18c is configured to face, and lie parallel to, the front surface 22 of the first solar cell 20, as shown in FIG. 4. Similarly, the front surface 48 is configured to face, and lie parallel to, the back surface 34 of the second solar cell 30.

The large contact area between third section 18c and the solar cell surfaces means that any force, or pressure, at the overlapping region 15 is distributed in a widthwise direction of the first and second solar cells 20, 30 (i.e. the horizontal direction in FIG. 4). This then reduces the risk of damage to the solar cells due to external and/or thermal loading of the solar module 100. The reduced height of the third section 18c also reduces the height of the overlapping region 15, as is most clearly shown in FIG. 5, which increases the structural stability of the solar cells. It can also lead to an overall reduction in the height (i.e. thickness) of the overlapping solar cells, which thereby improves the packaging efficiency of the solar cell assembly 10.

The curved surfaces of the conductive elements 18 in the first section 18a increases the scattering of light which is incident upon the front surface 22, which leads to improved light absorption and device performance of the first solar cell 20. Similarly, the conductive elements 18 of the second section 18b are configured to scatter light which is either transmitted through the solar cell, or which is reflected from the rear plate 108 back towards the solar cell's back surface.

The first and second sections 18a, 18b of the conductive elements 18 have a width and a height (e.g. thickness) of around 0.2 mm. Each of the first and second sections 18a, 18b are configured to extend substantially across the respective solar cell surface onto which they are overlaid. Each of the third sections 18c has a width of around 0.24 mm and a height (e.g., thickness) of around 0.08 mm. Accordingly, the third sections 18c are around 120% wider and around 40% of the height of the first and second sections 18a, 18b.

As described above, the electrode assembly 12 comprises an insulating and optically transparent film 40 in which at least a portion of the conductive elements 18 are embedded. The first and second sections 18a, 18b of the plurality of conductive elements 18 are each arranged in separate film portions. For example, the front connector 12a comprises a first film portion which defines a front-film portion 42 and the back connector 12b comprises a second film portion which defines a back-film portion 44. However, it is noted that the conductive elements 18 in the third section 18c are free from any film, or foil, covering.

According to an exemplary arrangement of the solar cell assembly 10, each of the first and second sections 18a, 18b of the conductive elements 18 is attached to a surface of its respective film 42, 44 that faces the solar cell. This “solar cell facing surface” of the films 42, 44 is coated with an adhesive which adheres the conductive elements to their respective films 42, 44.

With reference to FIG. 3, the film portions 42, 44 are arranged to contact the surfaces of the solar cells in the areas in-between the conductive elements 18 and the front finger electrodes 26, 28. In an exemplary arrangement of the solar cell assembly 10 each of the films portions 42, 44 is configured to at least partially (e.g. completely) envelope, or surround, the respective conductive elements 18 and the respective finger electrodes 26, 38.

The film portions 42, 44 are arranged to provide adhesion between the solar cells and the conductive elements 18 so that the conductive elements are correctly arranged on the solar cells (i.e. aligned with the finger electrodes). In an exemplary embodiment, the front and back film portions 42, 44 do not fully cover the respective surfaces of the solar cells. For example, the film portions are not arranged in the overlapping region 15 between the solar cells 20, 30, as shown in FIG. 5.

Further, the front-film portion 42 does not extend to the end of the front surface 32 of the second solar cell 30 which overlaps the first solar cell 20, as is clearly shown in FIG. 5.

Whilst the front and back film portions 42, 44 shown in the drawings comprise substantially planar bottom and top surfaces, respectively. It will be understood that the films 40 (i.e. the film portions 42, 44) may be configured to conform to the structural components of solar cells and/or conductive elements. Accordingly, the films 40 may be comprised of elongate channels recessed towards the solar cells in the regions of the solar cell surfaces in-between conductive elements, and may form ridges/protuberances over the structures electrodes (e.g. finger electrodes and conductive elements) where they are present.

The front and back film portions 42, 44 may be thinner than the conductive elements 18 (e.g. the non-compressed first and second sections 18a, 18b of the conductive elements). For example, the non-compressed first and second sections 18a, 18b of the conductive elements 18 may have a thickness of between 200 μm to 350 μm (e.g., around 200 μm, or 0.2 mm), whereas the films have a thickness of between 50 μm to 100 μm (e.g., around 75 μm, or 0.075 mm).

The front and back film portions 42, 44 are each formed of a polymer material having a high ductility, good insulating characteristics, optical transparency and thermal stability, resistance to shrinkage. An exemplary polymer material is comprised of modified ethylene tetrafluoroethylene. The front and back film portions 42, 44 are applied with heat and pressure onto the respective surfaces of the solar cells so that the films will conform to the finger electrodes and conductive elements arranged thereon.

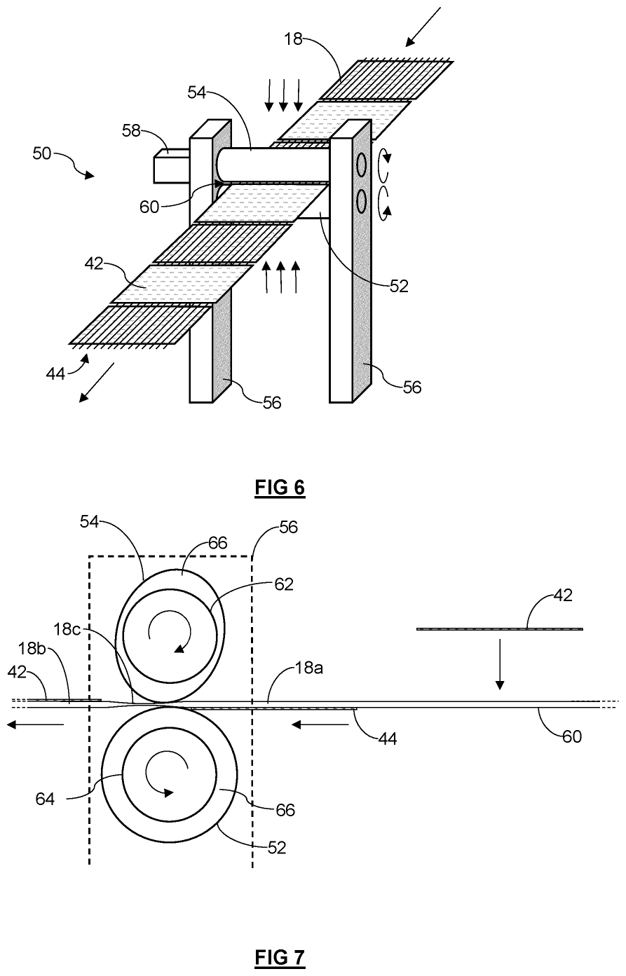

An apparatus 50 used to manufacture the electrode assembly 12 will now be described with reference to FIGS. 6 and 7. In particular, the apparatus 50 is configured to form the third section 18c of the plurality of elongate conducting elements 18.

The apparatus 50 includes a first roll 52 and a second roll 54 which are rotatably mounted to a pair of supports 56 that are arranged at the axial ends of the rolls 52, 54. The first and second rolls 52, 54 are axially parallel and radially spaced apart from each other to define a gap 60 therebetween. During operation of the apparatus 50, a plurality of conductive elements 18 are fed through the gap 60 between the first and second rolls 52, 54. The apparatus 50 is configured to periodically deform successive sections of conductive elements 18, as will be described in more detail below.

The first roll 52 is arranged vertically above the second roll 54, as is most clearly shown in FIG. 7. Specifically, the rotation axis of the first roll 52 is arranged vertically above the rotation axis of the second roll 54. Accordingly, the first and second rolls 52, 54 define upper and lower rolls of the apparatus 50, respectively.

Each of the rolls 52, 54 comprises an axle surrounded by an outer body. The outer body is formed of a resilient material, such as hardened steel, which is configured to resist deformation due to the roll's interaction with the plurality of conductive elements. It will be appreciated, however, that the rolls may be formed of different materials without departing from the scope of the present invention.

The first roll 52 includes a first axle 62 and the second roll 54 has a second axle 64, as shown most clearly in FIG. 7. The first and second axles 62, 64 are received within respective apertures provided in the supports 56. A set of bearings are provided (not shown) between each of the axles 62, 64 and the receiving apertures. The bearings are configured to enable the rolls 52, 54 to rotate freely with respect to the supports 56 during the operation of the apparatus 50.

An actuator 58 is coupled to the first and second rolls 52, 54, and is configured to control their rotation. The actuator 58 includes an electric motor which is coupled to the first and second axles 62, 64 by a drive belt (not shown). The drive belt is configured to transfer power from the electric motor to the rolls' axles 62, 64, as would be understood by the skilled person. The actuator 58 is configured to rotate the rolls 52, 54 at substantially the same speed (i.e. the same number of rotations per minute

The actuator 58 is configured to rotate the first roll 52 in an opposite direction to that of the second roll 54, so that the rolls work together to push and pull the conductive elements 18 through the gap 60. For example, when viewed from the right side of the apparatus 50, as shown in FIG. 7, then the first roll 52 is rotated in an anti-clockwise direction and the second roll 54 is rotated in a clockwise direction.

Each of the supports 56 comprises an elongate pillar, or column, which is arranged longitudinally in a vertical orientation, as shown in FIG. 6. Each of the supports 56 includes an upper end which is attached to the first and second rolls 52, 54. A lower end of each of the supports 56 is arranged on the ground and is thereby configured to support the weight of the apparatus 50.

As is described above, the apparatus 50 is configured to receive a plurality of conductive elements 18 through the gap 50 between the first and second rolls 52, 54. The conductive elements 18 are arranged to be substantially parallel to one another in a longitudinal direction and substantially spaced apart in a transverse direction, as is most clearly shown in FIG. 6.

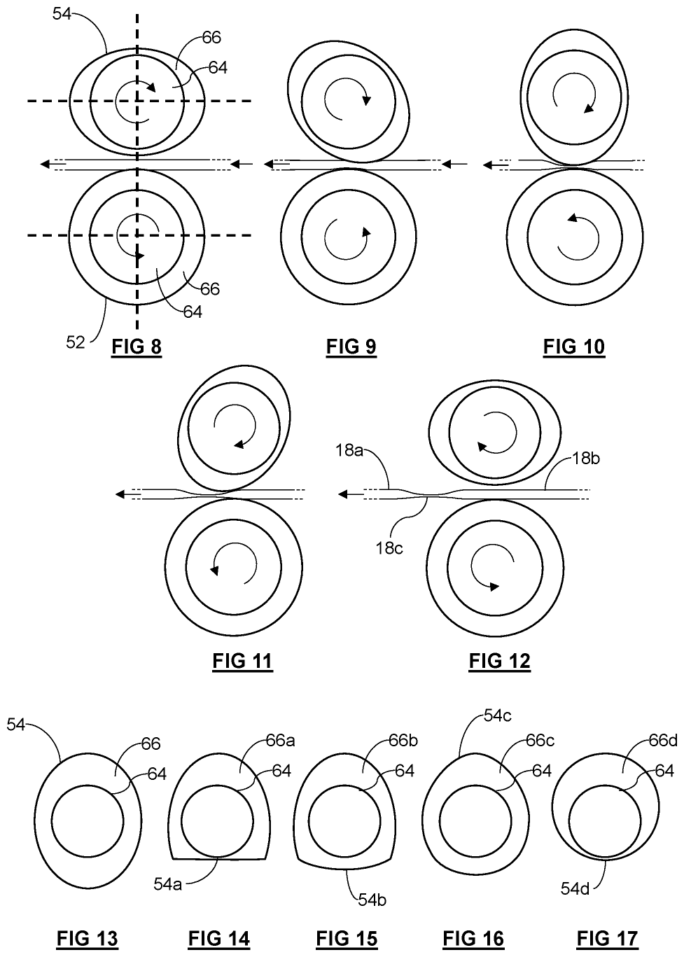

The first roll 52 has a circular cross-section and the first axle 62 (i.e. which defines the rotational axis of the first roll 52) is substantially aligned with the geometric centre of the circular cross-section (i.e. which defines the geometric axis of the first roll 52). This means that the first roll 52 is concentrically aligned with the first axle 62, as shown most clearly in FIG. 8.

The second roll 54 has an elliptical cross-section comprising two-fold symmetry, as illustrated by the dashed lines in FIG. 8. The elliptical cross-section of the second roll 54 comprises a major axis and a minor axis, which define diameters (i.e. lines through the geometric centre) of the elliptical cross-section. The major axis is the longest diameter and the minor axis the shortest. Accordingly, the major axis connects between two eccentric ends of the elliptical cross-section and the minor axis connects between two non-eccentric ends.

The second axle 64 (i.e. which defines the rotational axis of the second roll 54) is substantially aligned with the geometric centre of the roll's elliptical cross-section (i.e. which defines the geometric axis of the second roll 54). Furthermore, each the rotational and geometric axes of the first and second rolls 52, 54 all lie in a common vertical plane. The axes remain in the same vertical plane as the rolls 52, 54 are rotated, as illustrated in FIGS. 8 to 12.

Accordingly, the second roll 54 is configured such that, when it rotates, the gap 60 between the first and second rolls 52, 54 is reduced in a radial direction of the second roll 54. This reduction in the height (in the vertical direction shown in FIG. 7) of the gap 60 leads to a compressive force being applied to successive periodic sections of the plurality of conductive elements 18.

The first and second rolls 52, 54 enable continuous manufacturing of the electrode assemblies 12 by periodically reducing the height (in the vertical direction shown in FIG. 7) of the successive periodic sections, as the conductive elements 18 are fed through the gap 60 between the rolls 52, 54. This periodic application of a compressive force occurs without having to pause, or stop, the electrode assembly manufacturing process.

The resulting periodic sections define the third sections 18c of the above described plurality of conductive elements 18. Accordingly, the apparatus 50 provides a means of fabricating an electrode assembly 12 having a deformed interconnecting section 12c which can be arranged within the overlapping region of the first and second solar cells 20, 30 of the solar cell assembly 10.

As described above, the second roll 54 is configured to reduce the gap 60 between the first and second rolls 52, 54 in a periodic manner when the rolls rotate. This change in the size of the gap 60 will now be described with reference to FIGS. 8 to 12.

Starting with FIG. 8, the second roll 54 is arranged such that its major axis is parallel with the longitudinal axes of the conductive elements 18. The conductive elements 18 extend through the gap 60 between the rolls. When the rolls are arranged as shown in FIG. 8, then the gap 60 between the first and second rolls 52, 54 is at a maximum.

The portion of the conductive elements 18 which is arranged directly within the gap 60 is configured such that its front surface 48 is arranged to face the lowermost surface of the second roll 54, and a back surface 46 of the conductive elements 18 is arranged to face the uppermost surface of the first roll 52. The first roll 52 is arranged below the second roll 54 such that the conductive elements 18 rest upon the uppermost surface of the first roll 52 due to gravity. The second roll 54 is configured such that its lowermost surface is spaced apart from the conductive elements 18, as is shown in FIG. 8.

As the rolls rotate, the first roll 52 rotates in an anti-clockwise direction which pulls the conductive elements 18 in a substantially horizontal direction through the gap 60. The second roll 54 rotates in a clockwise direction so that one of its eccentric ends contacts the front surface 48 of the conductive elements 18, as shown in FIG. 9. The clockwise rotation of the second roll 54 causes the gap 60 between the first and second rolls 52, 54 to decrease. Upon contacting the conductive elements 18, any further rotation of the second roll 54 leads to a compressive force being applied to the elements, as the elements are compressed between the first and second rolls 52, 54.

As the rotation of the first and second rolls 52, 54 continues, the minimum gap 60 between the rolls is achieved when the second roll 54 reaches the position in which its major axis is perpendicular to the longitudinal axis of the elongate elements 18, as shown in FIG. 10. This position corresponds to the greatest compressive force being applied to the conductive elements 18.

As the first and second rolls 52, 54 rotate further, the gap 60 between the rolls begins to increase, as shown in FIG. 11. The second roll 54 separates from the front surface 48 of the conductive elements 18 to leave behind a deformed section of the conductive elements 18.

The front and back surfaces of the conductive elements 18 are both deformed by the respective first and second rolls 52, 54. Accordingly, the conductive element 18 is provided with opposing concave surfaces which correspond to the curved surfaces of the first and second rolls 52, 54.

FIG. 12 shows the first and second rolls 52, 54 having completed a 180-degree rotation. Once again, the second roll 54 is arranged such that its major axis is parallel with the longitudinal axes of the conductive elements 18. The gap 60 between the first and second rolls 52, 54 is again at a maximum, such that the conductive elements 18 are only in contact with the first roll 52 (i.e. the second roll 54 is spaced apart from the conductive elements 18). However, the second roll's eccentric end is now pointing in an opposite direction to that which it was pointing at the beginning of the rotation.

The maximum distance between first and second rolls 52, 54 (e.g., at the point of greatest separation between the rolls) is at least 0.3 mm and/or up to 5 mm. Accordingly, the distance between the rolls at their point of greatest separation is configured so that both rolls do not contact the conductive elements 18 at the same time, because the thickness of the non-compressed conductive elements 18 (e.g., around 0.2 mm) is not as thick as the maximum gap between the rolls (e.g., at least 0.3 mm).

The minimum distance between the first and second rolls 52, 54 (e.g., at the narrowest point between the rolls) is at least 0.05 mm and/or up to 4.75 mm. Accordingly, the gap between the rolls at their narrowest point is periodically less than the thickness of the non-compressed conductive elements (e.g., around 0.2 mm), which causes the rolls to periodically compress the height of the conductive elements (e.g., to around 0.08 mm) as the rolls rotate. For example, the maximum distance between the rolls is around 0.5 mm and the minimum distance between the rolls is around 0.08 mm.

According to the above, it will be understood that the rolls 52, 54 are configured such that a distance between the surfaces of the first and second rolls 52, 54 are caused to periodically decrease and increase as the rolls rotate. As such, the apparatus 50 defines a conductive element deforming apparatus.

The apparatus 50 can be operated continuously to deform periodic sections of the conductive elements 18 with each 180-degree rotation of the second roll 54. During the rotation of the rolls. As described above, the second roll 54 is separated from the conductive elements 18 during part of its rotation. The second roll 54 does not apply a compressive force on the intervening sections of the conductive elements 18. The apparatus 50 is configured, therefore, to only apply a compressive force to the successive periodic sections which are intended to be deformed.

The deformed section corresponds to the third section 18c of the plurality of elongate conducive elements 18, as described above with reference to FIG. 4. Further, the non-deformed sections arranged either side of the deformed section correspond to the first and second sections 18a, 18b of the conductive elements 18. A perimeter of the cross section of the second roll 54 defines a length which corresponds to the combined length of the first, second and third sections 18a, 18b, 18c of the plurality of conductive elements 18. This enables the deformed sections to be spaced apart by the correct distance, such that the non-deformed first and second sections 18a, 18b are sized to fit on the respective front and back surfaces 22, 34 of the first and second solar cells 20, 30.

In an exemplary arrangement, every alternate deformed section is cut away from the conductive elements 18 to leave behind a single deformed section (i.e. the third section 18c) coupled between two non-deformed sections (i.e. the first and second section 18a, 18b). In this arrangement, the permitter of the second roll 54 is greater than the combined length of the first, second and third section 18a, 18b, 18c in order to account for the length of the removed alternate deformed section.

Due to the curvature of the first and second rolls 52, 54, the thickness of the conductive elements 18 reduces progressively in a lengthways direction, the lengthways direction extending from the non-deformed sections to the deformed sections. This provides a smooth transition between the first and third sections 18a, 18c, and between the third and second sections 18c, 18b, as shown most clearly in FIG. 4. These transition regions combine some of the enhanced light scattering characteristics of the rounded elements (i.e. the non-deformed parts of the first and second sections 18a, 18b) with the enhanced charge extraction properties associated with the flattened elements (i.e. the third section 18c).

The deformed region of each of the conductive elements 18 (e.g. which encompasses the first, second and third sections 18a-c) is configured such that its upper and lower surfaces are substantially curved, when viewed in an axial section of the conductive element 18 (as shown in FIGS. 5, 7, 11 and 12). The tapered profile of the conductive elements 18 contrasts with deformed regions produced by other manufacturing methods. For example, a stamping method may produce deformed regions which exhibit a stepped profile, which defines the step change in the thickness of the conductive elements between the non-compressed and compressed regions.

The second roll 54 may be configured with different cross-sectional shapes, as shown in FIGS. 13, 14, 15, 16 and 17, without departing from the scope of the present invention. The roll 54 shown in FIG. 13 has the same elliptical cross-section as described above in relation to the apparatus 50 shown in FIGS. 6 and 7.

An alternative arrangement of the second roll 54a is shown in FIG. 14, in which the outer body 66a comprises a cross-section shaped as an elliptical segment. In this way, the outer body 66a comprises a first surface which is substantially flat, and a second surface which is configured to curve outwardly (i.e. the second surface is convex).

FIG. 15 illustrates a further alternative arrangement of the second roll 54b which comprises a first surface and a second surface. The first and second surfaces curve outwardly (i.e. the surfaces are convex) and wherein the first surface has a greater radius of curvature than the second surface. In this arrangement, the curved first surface replaces the substantially flat first surface of the roll 54a which is shown in FIG. 14.

A yet further alternative arrangement of the second roll 54c is shown in FIG. 16, in which the outer body 66c has an elliptical cross-section having only one axis of symmetry. According to this arrangement, the roll 54c is configured with an an egg-shaped cross-section.

In each of the arrangements shown in FIGS. 13 to 16, the rolls 54, 54a, 54b, 54c are all configured such that their geometric axes are substantially aligned with their respective rotational axes. Accordingly, the periodic reduction in the gap 60 between the first and second rolls is determined by the shape of the second rolls 54, 54a-c, and in particular the cross-sectional shape of their outer bodies 66, 66a-c.

In an alternative arrangement shown in FIG. 17, the roll 54d is configured such that its geometric axis is substantially misaligned with its rotational axis. In particular, the roll 54d comprises an outer body 66d which is configured with a circular cross-section having a geometric centre (i.e. which defines the geometric axis of the roll 54d). The axle 64 of the second roll 54d is radially offset from the geometric centre of its outer body 66d. The resulting misalignment between the geometric and rotational axes means that, when the second roll's axle 64 is rotated, it causes the outer body 66d to rotate eccentrically about the rotational axis. This eccentric rotation of the roll 54d leads to a periodic reduction in the gap between the first and second rolls of the apparatus. In this arrangement, the compressive forces being applied to the conductive elements are achieved due to the misalignment between the geometric and rotational axes of the second roll 54d.

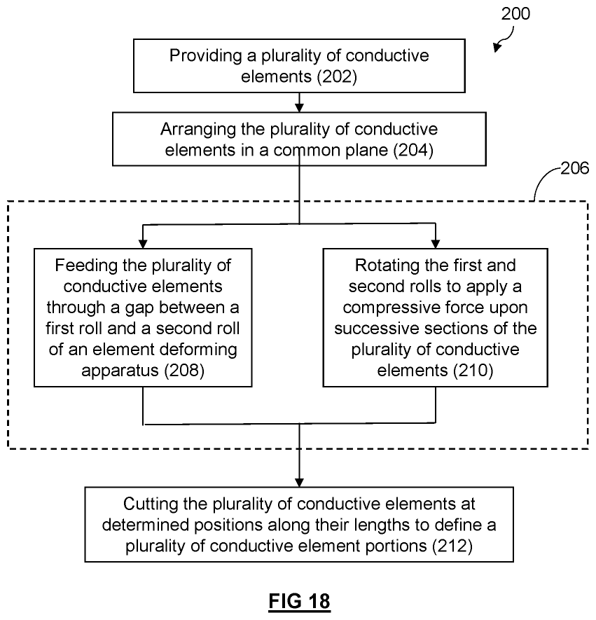

An exemplary method of manufacturing the electrode assembly 12 will now be described with reference to FIGS. 6 to 12, which illustrate the apparatus 50 used to manufacture the electrode assembly 12. Reference will also be made to FIG. 18, which shows a flow chart of the corresponding method steps.

The method commences with a first step 202 in which there is provided a plurality of conductive elements 18. In a second step 204, the conductive elements 18 are arranged in a common plane such that they lie substantially parallel to one another in a longitudinal direction. The conductive elements 18 are also spaced apart in a transverse direction, as shown in FIG. 6.

The second step 204 also includes applying an electrically insulating optically transparent film to the conductive elements 18, as shown in FIG. 7. A front film portion 42 is applied to the back surface 46 of the first section 18a and a back-film portion 44 is applied to the front surface of the second section 18b. The application of the film portions 42, 44 to the conductive elements 18 helps to maintain the relative positions of the conductive elements 18 (e.g. by maintaining the transverse direction) as the elements are fed through the apparatus 50.

The method proceeds with method step 206, which comprises reducing the height of the third section 18c of the plurality of conductive elements 18 using the element deforming apparatus 50, as described above. In particular, this includes the method step 208 of feeding the plurality of conductive elements 18 at least partially through the gap 60 between the first and second rolls 52, 54. It also includes the method step 210 of rotating the first and second rolls 52, 54 to apply a compressive force upon successive third sections 18c. It will be appreciated that method steps 208 and 210 are carried out concurrently so that the apparatus 50 is configured to apply a compressive force to successive periodic sections of the conductive elements 18 in a continuous manner.

Once the thickness of the third sections 18c has been reduced (according to method step 206) then the method proceeds with method step 212 which involves cutting the plurality of conductive elements 18 at pre-determined positions along their lengths to define a plurality of conductive element portions.

Each of the conductive element portions includes a pair of non-deformed sections (i.e. the first and second sections 18a, 18b) coupled together by a deformed section (i.e. the third section 18c) as shown, for example, in FIG. 4. Accordingly, the method of cutting the conductive elements 18 includes removing every other deformed section along the length of the conductive elements 18. To achieve this, a first cut is made at the leading end of the first section 18a of the conductive element portion. In addition, a second cut is made at the trailing end of the second section 18b of the same conductive element portion. The leading and trailing ends of the respective first and second sections 18a, 18b are characterised as the boundaries beyond which the thickness of the elements' starts to reduce (i.e. the limit of the non-deformed sections).

By cutting the conductive elements 18 only after they have been deformed ensures that each conductive element remains in the same position (i.e. relative to any other element) during the deforming process. It also means that the elements can be held under tension (e.g. by additional sets of rolls arranged either side of the apparatus 50) which ensures that the elements are deformed in the correct position along their lengths.

An exemplary method of manufacturing the solar cell assembly 10 will now be described, with reference to FIGS. 1 to 5. The method commences with a first step in which there is provided a first solar cell 20, a second solar cell 30 and an electrode assembly 12, as described above.

Prior to manufacturing the solar cell assembly, the solar cells 20, 30 are manufactured in a conventional manner as would be understood by the person having ordinary skill in the art. In particular, the method includes configuring each of the solar cells with a conductive surface (or conductive portion) on their respective front and back surfaces. For example, this may be achieved through the deposition of electrically conductive material onto the front and back surfaces 22, 24, 32, 34 of the first and second solar cells 20, 30 to form the pluralities of front and back finger electrodes 26, 36, 28, 38, respectively.

According to an exemplary method, the finger electrodes 26, 36, 28, 38 are deposited onto their respective surfaces using a screen-printing process, as would be understood by the skilled person.

Once the plurality of finger electrodes 36, 38 are deposited onto the surfaces of the first and second solar cells 20, 30, the electrode assembly 12 can be connected to the solar cells 20, 30 to define a solar assembly 10, according to the present invention

As described above, the electrode assembly 12 includes a plurality of conductive elements portions having first, second and third sections 18a, 18b, 18c. First and second film portions 42, 44 are arranged on the conductive elements' first and second sections 18a, 18b, respectively, to define the front and back connector 12a, 12b of the electrode assembly 12.

The second solar cell 30 is arranged so that its back surface 34 faces in an upward direction. Once the second solar cell 30 is inverted, then the back connector 12b of the electrode assembly 12 is overlaid onto the back surface 34 of the second solar cell 30. Accordingly, the conductive elements 18 are overlaid onto the back surface 34 such that they sit perpendicular to the finger electrodes 38.

A portion of the conductive element's third sections 18c are arranged to overlay a portion of the back surface 34 of the second solar cell 30 at one of its longitudinal ends. This end portion of the back surface 34 will at least partially define the overlapping region 15 between the solar cells 20, 30, when the solar cells are overlaid together. Accordingly, the front surfaces of the conductive elements' second and third sections 18b, 18c are brought into contact with the back-finger electrodes 38 of the second solar cell 30.

The method proceeds with the first solar cell 20 being inverted and overlaid onto the front connector 12a. In so doing, the back surfaces 46 of the conductive elements' first sections 18a are brought into contact with the front surface 22 of the first solar cell 20. A portion of the conductive element's third sections 18c are arranged to overlay a portion of the first solar cell's front surface 22 at one of its longitudinal ends. This end portion of the front surface 22 at least partially defines the overlapping region 15 between the solar cells 20, 30, when they are overlaid together, as shown in FIG. 4.

The above method also involves partially overlaying the front surface 22 of the first solar cell 20 onto the back surface 34 of the second solar cell 30. In this way, the third sections 18c of the conductive elements 18 are arranged in the overlapping region 15, which is thereby defined between the partially overlapping surfaces of the first and second solar cells 20, 30.

The method also includes heating and/or applying pressure to the conductive elements 18 of the front and back connectors 12a, 12b to bond the elements to the respective surfaces of the first and second solar cell 20, 30 under a compressive force. In particular, the conductive elements 18 are provided with a coating comprised of materials which have melting points which are lower than the materials from which the conductive elements are formed. The coating is at least partially melted by the application of heat and pressure, which causes the coating to flow towards the solar cells' surfaces. Once the coating has cooled and solidified, it forms an ohmic contact with the underlying finger electrodes 36, 38. The application of heat and pressure also laminates the front and back films 42, 44 onto the respective front and back surfaces 22, 34 of the solar cells 20, 30.

It will be appreciated that at least some of the above described method steps may be undertaken concurrently or in any order. For example, the method steps which involve inverting and arranging the first and second solar cells 20, 30 with respect to the electrode assembly 12 may take place at substantially the same time. Similarly, the front and back connectors 12a, 12b may also be connected to the respective front and back surfaces 22, 34 of the first and second solar cells 20, 30 at the same time.

As a result of the above described method, the front and back connectors 12a, 12b of the electrode assembly 12 are both mechanically and electrically coupled to the respective first and second solar cells 20, 30 to form a solar cell assembly 10 according to the present invention.

It will be understood that the invention is not limited to the embodiments above described and various modifications and improvements can be made without departing from the concepts described herein. Except where mutually exclusive, any of the features may be employed separately or in combination with any other features and the disclosure extends to and includes all combinations and sub-combinations of one or more features described herein.

### FEATURE LIST

Solar cell assembly 10
Electrode assembly 12, 14, 16
Overlapping region 15
Front connector 12a
Back connector 12b
Interconnecting portion 12c
Conductive element 18
First section of the conductive elements 18a
Second section of the conductive elements 18b
Third section of the conductive elements 18c
First solar cell 20
First solar cell-front surface 22
First solar cell-back surface 24
Front finger electrodes 26
Back finger electrodes 28
Second solar cell 30
Second solar cell-front surface 32
Second solar cell-back surface 34
Front finger electrodes 36
Back finger electrodes 38
Film 40
Front-film portion 42
Back-film portion 44
Third section conductive element-back surface 46
Third section conductive element-front surface 48
Apparatus 50
First roll 52
Second roll 54
Supports 56
Actuator 58
Rolls gap 60
First roll axle 62
Second roll axle 64
Outer body 66
Solar module 100
Support assembly 102
Front plate 104
Central chamber 106
Back plate 108

1. An apparatus for manufacturing an electrode assembly for connecting a front surface of a first solar cell to a back surface of a second solar cell, the electrode assembly comprising a plurality of conductive elements arranged substantially parallel to one another in a longitudinal direction and substantially spaced apart in a transverse direction, the apparatus comprising:
a first roll and a second roll spaced apart to define a gap therebetween for receiving the plurality of conductive elements; and
an actuator configured to rotate at least one of the first and second rolls;
wherein the apparatus is configured to periodically reduce the gap between the first and second rolls to periodically apply a compressive force to the plurality of conductive elements arranged in the gap when the at least one of the first and second rolls rotates.

2. An apparatus according to claim 1, wherein the apparatus is configured to periodically not apply the compressive force to the plurality of conductive elements, and optionally is configured to alternate between applying the compressive force and not applying the compressive force.

3. An apparatus according to claim 1, wherein the second roll is arranged substantially above the first roll.

4. An apparatus according to claim 1, wherein the maximum gap between first and second rolls is at least 0.3 mm and/or up to 5 mm, and the minimum gap between the first and second rolls is at least 0.05 mm and/or up to 4.75 mm.

5. An apparatus according to claim 1, wherein the first roll comprises a substantially circular cross-section and the second roll is configured to periodically reduce the gap between the first and second rolls.

6. An apparatus according to claim 1 wherein, the plurality of conductive elements each comprising a first section for contacting only the front surface of the first solar cell, a second section for contacting only the back surface of the second solar cell, and a third section for contacting both the front surface of the first solar cell and the back surface of the second solar cell, the third section being configured to connect the first section to the second section; wherein a perimeter of the cross section of the at least one of the first and second rolls defines a length which corresponds to the combined length of the first, second and third sections of the plurality of conductive elements.

7. An apparatus according to claim 1, wherein the at least one of the first and second rolls comprises a cross-section geometry configured such that, when it rotates, the gap between the first and second rolls periodically reduces in the radial direction.

8. An apparatus according to claim 7, wherein the at least one of the first and second rolls comprises an elliptical cross-section.

9. An apparatus according to claim 8, wherein the elliptical cross-section has two axes of symmetry.

10. An apparatus according to claim 8, wherein the elliptical cross-section has only one axis of symmetry.

11. An apparatus according to claim 1, wherein the at least one of the first and second rolls comprises a cross-section shaped as an elliptical segment.

12. An apparatus according to claim 1, wherein the at least one of the first and second rolls comprises a first surface and a second surface, the first and second surfaces being configured to curve outwardly, wherein the first surface has a variable radius of curvature and the second surface has a constant radius of curvature.

13. An apparatus according to claim 1, wherein the at least one of the first and second rolls comprises a cross-section having a geometric centre, wherein the at least one of the first and second rolls is configured with a rotation axis that is misaligned with the geometric centre.

14. A method of manufacturing an electrode assembly for connecting a front surface of a first solar cell to a back surface of a second solar cell, the method comprising:
providing a plurality of conductive elements;
arranging the plurality of conductive elements in a common plane such that they lie substantially parallel to one another in a longitudinal direction, and are substantially spaced apart in a transverse direction; and
periodically reducing the height of a section of the plurality of conductive elements comprising:
providing a first roll and a second roll which are spaced apart to define a gap therebetween for receiving the plurality of conductive elements;
feeding the plurality of conductive elements at least partially through the gap between the first and second rolls; and
periodically reducing the gap between the first and second rolls, when at least one of the first and second rolls rotate, to periodically apply a compressive force to the plurality of conductive elements arranged in the gap.

15. A method according to claim 14, wherein the method comprises periodically increasing the gap between the first and second rolls, when the at least one of the first and second rolls rotate, to periodically not apply the compressive force to the plurality of conductive elements.

16. A method according to claim 14, wherein the method comprises arranging an electrically insulating and optically transparent film onto a non-compressed section of the plurality of conductive elements.

17. A method according to claim 16, wherein the method comprises arranging the electrically insulating and optically transparent film prior to feeding the plurality of conductive elements at least partially through the gap between the first and second rolls.

18. A method according to claim 16, wherein the electrically insulating and optically transparent film is arranged so as not to cover a compressed section of the plurality of conductive elements.

19. A method according to claim 14, wherein the method comprises cutting the plurality of conductive elements to define a plurality of conductive element portions, each portion comprising a compressed section arranged between two non-compressed sections.

20. A method according to claim 19, wherein the method step of cutting the conductive elements occurs after the method step of reducing the height of the compressed section.

21. A method of manufacturing a solar cell assembly, the method comprising:
manufacturing an electrode assembly according to claim 14, wherein each of the plurality of conductive elements comprise a first section for only contacting the front surface of the first solar cell, a second section for only contacting the back surface of the second solar cell, and a third section for contacting both the front surface of the first solar cell and the back surface of the second solar cell, the third section being configured to connect the first section to the second section:
providing a first solar cell and a second solar cell;
arranging the second solar cell such that its back surface is facing in a substantially upward direction;
overlaying the second section of the plurality of conductive elements of the electrode assembly onto the back surface of the second solar cell;
overlaying the front surface of the first solar cell onto the first section of the plurality of conductive elements such that the front surface of the first solar cell partially overlaps the back surface of the second solar cell and such that the third section of the plurality of conductive elements is arranged between the overlapping parts of the front surface of the first solar cell and the back surface of the second solar cell; and
connecting the first and second sections of the plurality of conductive elements to the respective front and back surfaces of the first and second solar cells.

22. An electrode assembly manufactured according to the method of claim 14.

23. The electrode assembly according to claim 22, the plurality of conductive elements each comprising a first section for contacting only the front surface of the first solar cell, a second section for contacting only the back surface of the second solar cell, and a third section for contacting both the front surface of the first solar cell and the back surface of the second solar cell, the third section being configured to connect the first section to the second section; wherein the thickness of the plurality of conductive elements reduces progressively in a lengthways direction along the plurality of conductive elements from each of the first and second sections towards the third section.

24. A solar cell assembly manufactured according to the method of claim 21, the plurality of conductive elements being configured to electrically couple a front surface of the first solar cell with a back surface of the second solar cell, wherein the back surface of the second solar cell is configured to partially overlap the front surface of the first solar cell, wherein the third section of the plurality of conductive elements is arranged between the partially overlapping surfaces of the first and second solar cells.

25. An electrode assembly for connecting a front surface of a first solar cell to a back surface of a second solar cell, the electrode assembly comprising a plurality of conductive elements arranged substantially parallel to one another in a longitudinal direction and substantially spaced apart in a transverse direction, the plurality of conductive elements each comprising a first section for contacting only the front surface of the first solar cell, a second section for contacting only the back surface of the second solar cell, and a third section for contacting both the front surface of the first solar cell and the back surface of the second solar cell, the third section being configured to connect the first section to the second section;
wherein the thickness of the plurality of conductive elements reduces progressively in a lengthways direction along the plurality of conductive elements from each of the first and second sections towards the third section.

26. An electrode assembly according to claim 25, wherein each of the conductive elements is configured with a curved surface when viewed in an axial section of the conductive element.

27. An electrode assembly according to claim 25, wherein each of the conductive elements is configured with opposing concave surfaces.
